(19) United States
(12) Patent Application Publication
(10) Pub. No.: US 2005/0062058 A1
(43) Pub. Date: Mar. 24, 2005

(54) Semiconductor light emitting device and manufacturing method for the same

(75) Inventor: Masaya Ishida, Kashihara-shi (JP)

Correspondence Address: Barry E. Bretschneider;Morrison & Foerster LLP, Suite 300, 1650 Tysons Boulevard, McLean, VA, 22102, US

(73) Assignee: Sharp Kabushiki Kaisha, Osaka (JP)

(21) Appl. No.: 10/947,252

(22) Filed: Sep. 23, 2004

(30) Foreign Application Priority Data
Sep. 24, 2003 (JP) 2003-331281

(51) Int. Cl. H01L 33/00; H01L 29/22

(52) U.S. Cl. 257/99

(57) ABSTRACT

An object of the present invention is to provide a semiconductor light emitting device having a long lifespan by improving yield in mounting. In order to achieve this object, a semiconductor light emitting device includes a semiconductor light emitting element chip having an n-type GaN substrate, a heat sink made of SiC onto which the semiconductor light emitting element chip is mounted, a solder made of AuSn which joins the n-type GaN substrate to the heat sink, a support base onto which the heat sink is mounted, and a solder made of In or SnAgCu which joins the heat sink to the support base. The solder has a thickness in a range from 1 μm or more to 20 μm or less, and the heat sink has a thickness in a range from 100 μm or more to 500 μm or less.

### BACKGROUND OF THE INVENTION

1. Field of the Invention

The present invention relates to a semiconductor light emitting device (including a semiconductor laser device) and a manufacturing method for the same. In particular, the present invention relates to mounting of a semiconductor light emitting element chip and mounting of a heat sink.

2. Description of the Prior Art

A semiconductor laser device having a laser chip that contains an active layer made of a nitride-based semiconductor represented by GaN, InN, AlN and mixed crystals of these semiconductors has been manufactured as a prototype. A laser element made of a nitride-based semiconductor has a high operation voltage and a driver for driving the laser has a low operation voltage. Therefore, a floating type laser is utilized in order to use such a driver, and it is necessary to insert and mount an insulative heat sink between the laser and a support base.

In assembly of a conventional semiconductor laser device, a laser chip is mounted on a heat sink and, then, a sheet-shaped solder foil is placed on a mounting part of a support base. Thereafter, the heat sink on which the laser chip has been placed is mounted on the solder foil. Conventionally, a thickness of the solder foil is 30 μm or more.

In JP-A 2003-31895, a semiconductor laser device is formed in a state where a main surface of a semiconductor laser chip is curved, achieving its long lifespan and improving its reliability. In this publication, there is no description about a thickness of solder that joins a stem (support base) to a sub-mount (heat sink).

However, a semiconductor laser device made of a nitride-based semiconductor has a high operation voltage of a laser element and has a large amount of heat generation. Therefore, in a case where a solder foil is utilized, the heat generated in the laser chip cannot be efficiently dissipated to the support base, causing property deterioration as temperature of a light emitting part increases. In addition, the laser chip easily moves upon mounting according to the above method, and a problem arises where variation in an angle of installment of a laser chip after mounting is large.

### SUMMARY OF THE INVENTION

An object of the present invention is to provide a semiconductor light emitting device having a long lifespan by improving yield in mounting. In addition, another object of the present invention is to provide a manufacturing method for such a semiconductor light emitting device.

In order to achieve the above objects, the present invention provides a semiconductor light emitting device comprising: a semiconductor light emitting element chip having a substrate made of a nitride-based compound semiconductor; a heat sink made of SiC onto which the semiconductor light emitting element chip is mounted; a first solder made of AuSn which joins the substrate to the heat sink; a support base onto which the heat sink is mounted; and a second solder made of SnAgCu or In which joins the heat sink to the support base.

This configuration allows the heat generated in the semiconductor light emitting element chip to be efficiently dissipated to the support base, so that property deterioration resulting from an increase in temperature of a light emitting part can be prevented. Accordingly, it is possible to extend the lifespan of the device.

Herein, the second solder has a thickness in a range from 1 μm or more to 20 μm or less; therefore, variation in the angle of installment is eliminated and the yield in mounting can be improved, leading to a long lifespan.

Preferably, the heat sink has a thickness in a range from 100 μm or more to 500 μm or less.

In the case where the thickness of the heat sink is less than 100 μm, a problem arises during conveyance upon die bonding and in the positioning of the heat sink, thus lowering the yield in mounting. On the other hand, in the case where the thickness of the heat sink exceeds 500 μm, the lifespan becomes 3000 hours or less, bringing rise to a problem in practical use of the device.

In addition, the present invention also provides a manufacturing method for a semiconductor light emitting device comprising a semiconductor light emitting element chip having a substrate made of a nitride-based compound semiconductor, a heat sink onto which the semiconductor light emitting element chip is mounted, a first solder which joins the substrate to the heat sink, a support base onto which the heat sink is mounted, and a second solder which joins the heat sink to the support base, and the method comprises the steps of: transcribing the second solder made of SnAgCu or In that has been fabricated in sheet form onto the support base; and mounting a heat sink, onto which the semiconductor light emitting element chip has been mounted, onto the support base via the second solder.

This configuration eliminates variation in the angle of installment of a semiconductor light emitting element chip and allows for an improvement in the yield in mounting, thus leading to a long lifespan.

Desirably, the second solder has a thickness in a range from 1 μm or more to 20 μm or less

According to the present invention, due to a particular solder material and a manufacturing method, the heat generated in the semiconductor light emitting element chip can be efficiently dissipated to the support base and the property deterioration resulting from an increase in the temperature of the light emitting part can be prevented. In addition, the thickness of the solder is reduced in comparison with the prior art, so that variation in the angle of installment of a semiconductor light emitting element chip is eliminated, and the yield in mounting is improved. As a result, a long lifespan of the light emitting element can be achieved.

### DESCRIPTION OF THE DRAWINGS

FIG. 1 is a schematic side view of a semiconductor laser device according to a first embodiment;

FIG. 2 is a schematic cross-sectional view of a semiconductor laser chip according to the first embodiment;

FIG. 3 is a table showing yields in mounting in the first embodiment and first to third comparative examples;

FIG. 4 is a table showing yields in mounting in a second embodiment and fourth to sixth comparative examples; and

FIG. 5 is a graph showing a relationship between lifespan of an element and a thickness of a heat sink according to the present invention.

### DESCRIPTION OF THE PREFERRED EMBODIMENTS

Hereinafter, embodiments of the present invention will be described with reference to the drawings.

First Embodiment

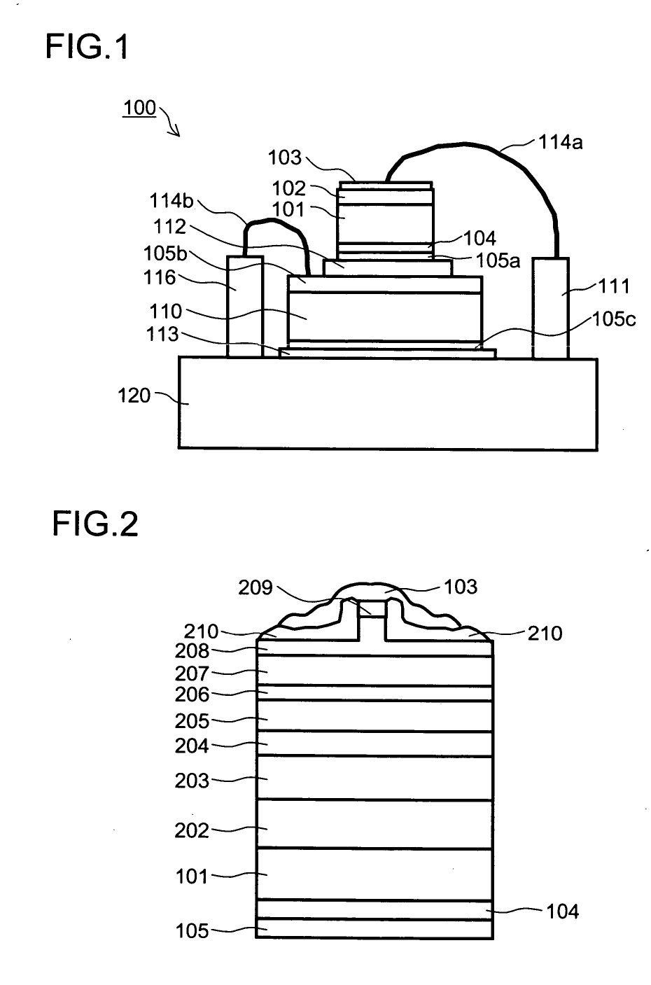

FIG. 1 is a schematic side view of a semiconductor laser device 100 according to a first embodiment. In FIG. 1, a layered body 102 of a nitride-based semiconductor is formed on a GaN substrate 101. In addition, a p-electrode 103 is provided on an upper surface of the layered body 102 of the nitride-based semiconductor, and an n-electrode 104 and a multi-layered metal film 105a for metallization are provided under a lower surface of the GaN substrate 101.

The basic configuration of a semiconductor laser chip used in the semiconductor laser device 100 according to the first embodiment is as described above, and details thereof will be described below.

The semiconductor laser chip is secured to and layered on a support base 120 via a heat sink 110. The semiconductor laser chip is joined with the p-electrode 103 facing upward to the heat sink 110 via a solder 112 and a multi-layered metal film 105b. Then, the heat sink 110 is joined to the support base 120 via a multi-layered metal film 105c and a solder 113. Here, SiC is used as a material of the heat sink 110, AuSn is used as a material of the solder 112, and In is used as the material of the solder 113.

In addition, the p-electrode 103 is electrically connected to a pin 111 by means of a wire 114a and the n-electrode 104 is electrically connected to a pin 116 by means of a wire 114b, thus forming a floating mounting. Here, the pins 111 and 116 are electrically connected to external connection terminals which are isolated from the support base 120. With this configuration, a current can be supplied to the semiconductor laser chip from the outside.

FIG. 2 is a schematic cross-sectional view of the semiconductor laser chip according to the first embodiment. In FIG. 2, an n-GaN contact layer 202, an n-AlGaN clad layer 203, an n-GaN guide layer 204, a GaInN multiple quantum well active layer 205, a p-AlGaN vaporization preventing layer 206, a p-GaN guide layer 207, a p-AlGaN clad layer 208 and a p-GaN contact layer 209 are layered on the GaN substrate 101 in this order. Stripe-shaped ridges that extend in a direction of a resonator are provided to the p-AlGaN clad layer 208 and the p-GaN contact layer 209. An insulating film 210 is provided between the p-electrode 103 and the p-AlGaN clad layer 208 as well as between the p-electrode 103 and the p-GaN contact layer 209, except for the ridge portions.

Here, the materials of the semiconductor laser chip are not limited to those shown in FIG. 2, but rather other nitride-based compound semiconductors can be used. For example, the p-AlGaN clad layer 208 may be replaced with p-AlGaInN, and the GaInN multiple quantum well active layer 205 may be replaced with GaInNAs, GaInNP or the like. In addition, the clad layers 203 and 208 may have a multi-layered structure or may use a multiple quantum well. Furthermore, a crack preventing layer such as InGaN may be inserted between the n-GaN contact layer 202 and the n-AlGaN clad layer 203, and a buffer layer may be inserted between the GaN substrate 101 and the n-GaN contact layer 202. In addition, the stripe-shaped ridges that extend in the direction of the resonator may be formed at the depth of the GaInN multiple quantum well active layer 205, the p-AlGaN vaporization preventing layer 206 and the p-GaN guide layer 207, in addition to the p-AlGaN clad layer 208 and the p-GaN contact layer 209.

As described above, the semiconductor laser chip used in the present embodiment has a so-called ridge stripe-type structure. Hereinafter, a manufacturing method for the semiconductor laser device 100 according to the present embodiment will be described with reference to FIGS. 1 and 2.

First, processes used for manufacturing semiconductor elements are appropriately applied so as to obtain a semiconductor laser wafer on the GaN substrate 101 where a number of semiconductor laser structures, each of which is shown in FIG. 2, are individually formed. The process for obtaining such a wafer is a well-known technology; therefore, its detailed description will not be given here. Herein, materials of the p-electrode 103 are Pd (15 nm)/Mo (15 nm)/Au (200 nm) from the side closer to the p-GaN contact layer 209.

In the present embodiment, though a thickness of the GaN substrate 101 is 350 μm upon crystal growth, a portion of the substrate is removed by means of polishing or etching from a bottom side of the GaN substrate 101 before formation of the n-electrode 104 so as to generally reduce a thickness of the wafer to approximately 40 to 150 μm. Thereafter, Ti (30 nm)/Al (150 nm) are formed from the side closer to the n-GaN contact layer 202 as the n-electrode 104 and, further, Mo (8 nm)/Pt (15 nm)/Au (250 nm) are formed as the multi-layered metal film 105a.

Next, laser edge surfaces are formed by means of cleavage so as to have a length of the resonator of 500 μm and, further, the wafer is divided into laser chips. The laser edge surfaces may be formed by means of etching and the division into chips may be carried out according to dicing, laser aberration method or the like. Properties of a laser chip obtained according to the present process are measured by pulse driving the laser chip in a chip state so as to find a threshold density of 3.5 kA/cm².

Next, a method for transcribing the solder foil 113 onto the support base 120 will be described. A Teflon tape having a length of 500 mm and a width of 500 μm is prepared, and In is deposited from a vapor form on this Teflon tape so as to have a thickness of approximately 10 μm. Subsequently, the Teflon tape with the In solder is positioned relative to the support base 120. After the positioning, a supersonic vibration of approximately 80 kHz is applied to this In solder through the Teflon tape, so that the In solder 113 of which the size is a length of 500 μm×a width of 500 μm×a thickness of 10 μm is transcribed onto the support base 120. Herein, the method for depositing the solder from a vapor form may be a conventional method that is used by heating and melting the material, a spattering method, an electron beam method, an MBE method or the like.

Next, the laser chip is mounted on the support base 120, onto which the In solder 113 has been transcribed, according to a die bonding method. Concretely speaking, the heat sink 110, on which the Au_{0.8}Sn_{0.2} solder 112 is deposited so as to have a thickness of 3 μm, and on which the multi-layered metal films 105b and 105c are formed, is heated to a temperature which is slightly higher than the melting point of the solder 112. When the solder 112 is melted, the laser chip obtained in the above process is placed with the n-electrode 104 facing downward on the heat sink 110, to which further pressure is applied appropriately so that the laser chip and the heat sink 110 become compatible with the solder 112. Thereafter, the heat sink 110 is cooled so that the solder 112 is solidified.

Next, the support base 120 onto which the In solder 113 has been transcribed is heated to a temperature slightly higher than the melting point of the solder 113. When the solder 113 is melted, the heat sink 110 on which the laser chip has been layered is placed so that the heat sink 110 and the support base 120 become compatible with the solder 113, and this process is completed when the solder is solidified.

Finally, a cap having a glass window on which a coating has been applied that makes a transmission of 98% or more at a wavelength of ±10 nm of oscillation of the laser chip is mounted on the support base 120 in a nitrogen atmosphere so as to obtain the semiconductor laser device 100.

In addition, in the present embodiment, though Pd/Mo/Au is used as p-electrode 103, Co, Cu, Ag, Ir, Sc, Au, Cr, Mo, La, W, Al, Ti, Y, La, Ce, Pr, Nd, Sm, Eu, Tb, Ti, Zr, Hf, V, Nb, Ta, Pt, Ni or compounds thereof, for example, may be used in place of Pd; Co, Cu, Ag, Ir, Sc, Au, Cr, Pd, La, W, Al, Tl, Y, La, Ce, Pr, Nd, Sm, Eu, Th, Ti, Zr, Hf, V, Nb, Ta, Pt, Ni or compounds thereof, for example, may be used in place of Mo; and Ni, Ag, Ga, In, Sn, Pb, Sb, Zn, Si, Ge, Al or compounds thereof may be used in place of Au. The film thicknesses are not limited to the above-described thicknesses.

In addition, though Ti/Al is used as the n-electrode 104, Hf may be used in place of Ti, and the film thickness is not limited to the above-described thickness. In addition, the cap mounting may be carried out in the air. In addition, in the present embodiment, though a GaN substrate is used for the fabrication of a laser chip, the substrate may be made of InN, AlN or mixed crystal semiconductors of GaN, InN and AlN in place of GaN.

In addition, SiC of the heat sink 110 may be any type of single crystal, polycrystal and amorphous, as long as it has insulating properties. In addition, the solder 112 is not limited to Au_{0.8}Sn_{0.2}, but rather may have any ratio of Au to Sn, as long as it is made of AuSn. Herein, the support base 120 is made of a metal of which a main component is Cu or Fe, and Ni film/Au film or Ni film/Cu film/Au film are plated in this order on the surface of the support base 120.

Thus obtained semiconductor laser device 100 is compared with those in first to third comparative examples. The first comparative example is a semiconductor laser device on which an SiC heat sink is mounted, wherein a laser chip is layered on an In solder foil having a thickness of 50 μm placed on a support base without transcribing In solder onto the support base. The second comparative example is a semiconductor laser device wherein Cu is utilized as a material of the heat sink. The third comparative example is a semiconductor laser device wherein Si is utilized as a material of the heat sink. Herein, the configurations which are not described in the first to third comparative examples are the same as in the first embodiment.

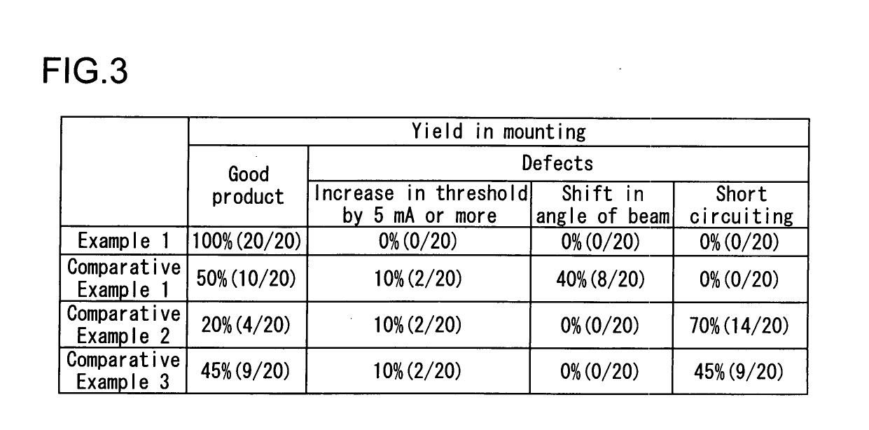

The respective 20 samples of the semiconductor laser devices of the first embodiment and the first to third comparative examples are fabricated and the following measurements are carried out. Properties of each semiconductor laser device are measured when pulse driven in a manner where a threshold is measured and a yield in mounting is evaluated. According to an evaluation standard of the yield in mounting, a chip of which the threshold has risen by 5 mA or more is determined to be inferior (defective) and a chip of which a deviation angle in a direction of radiation of a beam is ±2.5° or more is also determined as defective. The result of this is shown in FIG. 3. The yield in mounting of the first embodiment is 100%, while defects have occurred in mounting in the first to third comparative examples.

In addition, a semiconductor laser device of which a multi-layered metal film for metallization is made of Mo (8 nm)/Au (250 nm) is fabricated as an additional comparative example, and is mounted by using the same heat sink and material of solder as in the first embodiment, failing to obtain a sufficient mounting strength where the yield in mounting is 0%.

Next, an aging process is carried out on good products after mounting, when APC driven with 30 mW output at a temperature of 60° C. Herein, a ridge width of each sample is 2 μm and a length of a resonator is 500 μm. A lifespan of the semiconductor laser device 100 according to the first embodiment is 10,000 hours or more while lifespans of all the semiconductor laser devices according to the first to third comparative examples is 1,000 hours or less. As a result of this, the heat generated by the laser chip is efficiently dissipated to the support base 120 in the semiconductor laser device 100 according to the first embodiment, thus preventing the property deterioration resulting in an increase in temperature of a light emitting part.

Second Embodiment

A semiconductor laser device according to a second embodiment is obtained by changing the material of the solder 113 that is transcribed onto the support base 120 to SnAgCu in the semiconductor laser device according to the first embodiment. The same symbols as the component members of the first embodiment except for symbol 113a indicating the above-described solder will be used to describe the second embodiment.

A Teflon tape having a length of 500 mm and a width of 600 μm is prepared and SnAg_{0.03}Cu_{0.005} is deposited from a vapor form onto this Teflon tape so as to have a thickness of approximately 8 μm. Thereafter, the Teflon tape onto which an SnAgCu solder 113a has been deposited is positioned relative to the support base 120. After the positioning, a supersonic vibration of approximately 80 kHz is applied to the solder 113a through the Teflon tape, so that the solder 113a of which the size is a length of 500 μm×a width of 500 μm×a thickness of 8 μm is transcribed onto the support base 120.

As for a method for depositing the solder 113a from a vapor form, any method such as a conventional method which is used by heating and melting the material, a spattering method, an electron beam method or an MBE method may be used, and a source of deposition may be Sn, Ag and Cu individually; a mixed crystal of SnAgCu; a mixed crystal of SnAg and Cu; a mixed crystal of SnCu and Ag; or Sn and a mixed crystal of AgCu.

Next, a laser chip is mounted onto the support base 120, onto which the SnAgCu solder 113a has been transcribed, according to a die bonding method. This process is carried out as follows.

The heat sink 110, onto which the Au_{0.7}Sn_{0.3} solder 112 is deposited, and on which the multi-layered metal films 105b and 105c are formed, is heated to a temperature which is slightly higher than a melting point of the solder 112. When the solder is melted, the laser chip obtained in the same manner as in the first embodiment is placed with the n-electrode 104 facing downward on the heat sink 110, to which further pressure is applied appropriately so that the laser chip and the heat sink 110 become compatible with the solder 112. After that, the heat sink 110 is cooled so that the solder 112 is solidified.

Next, the support base 120 onto which the SnAg_{0.03}Cu_{0.005} solder 113a has been transcribed is heated to a temperature slightly higher than a melting point of the solder 113a. When the solder 113a is melted, the heat sink 110 on which the laser chip has been layered is placed so that the heat sink 110 and the support base 120 become compatible with the solder 113a, and this process is completed when the solder 113a is solidified.

Next, a cap having a glass window on which a coating has been applied that makes a transmission of 98% or more at a wavelength of ±10 nm of oscillation of the laser chip is mounted on the support base 120 in a nitrogen atmosphere so as to obtain the semiconductor laser device.

Herein, the solder 112 is not limited to SnAg_{0.03}Cu_{0.005}, but rather any ratios of Sn, Ag and Cu may be used as long as the ratio of Ag is 10% or less and the ratio of Cu is 8% or less.

Thus obtained semiconductor laser device is compared with those of fourth to sixth comparative examples. The fourth comparative example is a semiconductor laser device wherein a sheet-shaped SnAg_{0.03}Cu_{00.005} foil is used as the solder between the support base and the heat sink. The fifth comparative example is a semiconductor laser device wherein Cu is utilized as a material of the heat sink. The sixth comparative example is a semiconductor laser device where Si is utilized as a material of the heat sink. Here, the portions of the configurations which are not described in the fourth to sixth comparative examples are the same as in the second embodiment.

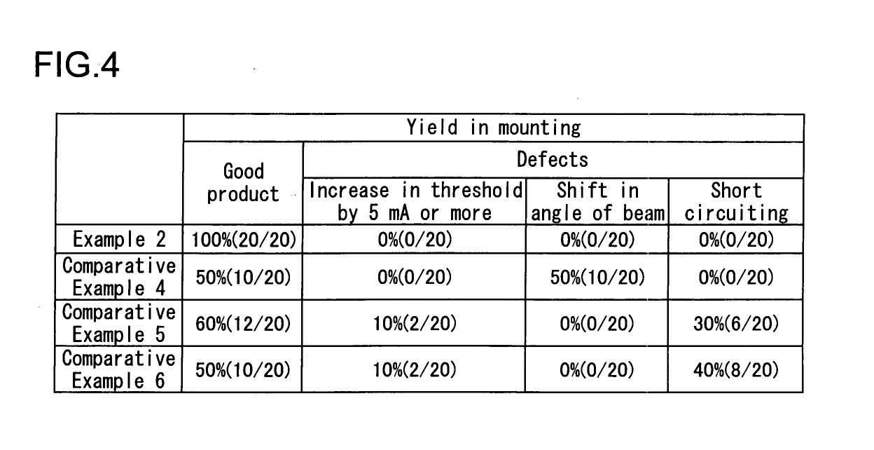

The respective 20 samples of semiconductor laser devices according to the second embodiment and the fourth to sixth comparative examples are fabricated so that the same measurements as in the first embodiment are carried out. The result of this is shown in FIG. 4. A yield in mounting of the second embodiment is 100%, while defects in mounting have occurred in the fourth to sixth comparative examples.

Next, an aging process is carried out on good products after mounting, when APC driven with 30 mW output at a temperature of 60° C. Here, a ridge width of each sample is 2 μm and a length of a resonator is 600 μm. A lifespan of the semiconductor laser device according to the second embodiment is 10,000 hours or more while lifespans of all the semiconductor laser devices according to the fourth to sixth comparative examples is 1,000 hours or less. As a result of this, the heat generated by the laser chip is efficiently dissipated to the support base 120 in the semiconductor laser device according to the second embodiment, thus preventing property deterioration resulting in an increase in temperature of a light emitting part.

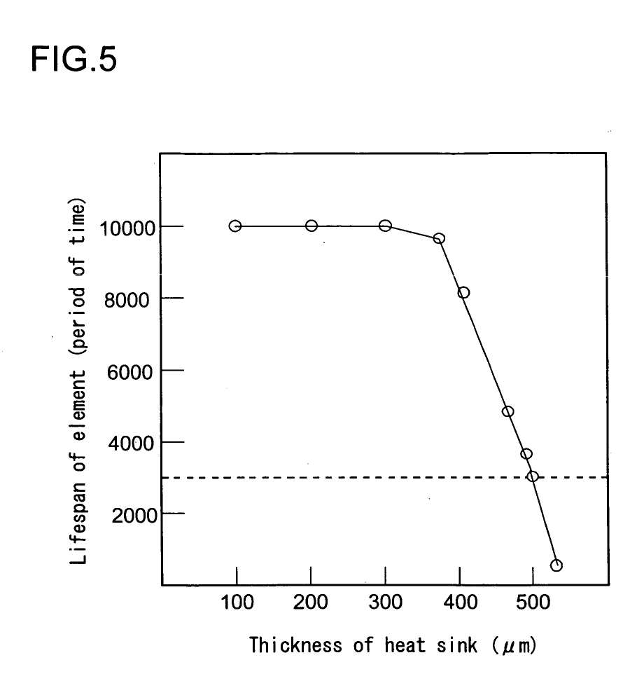

Next, the thickness of the heat sink 110 is changed and the same mounting as the present embodiment is carried out so that the yield in mounting is measured and the lifespan is evaluated. In the case where the thickness of the heat sink 110 is less than 100 μm, a problem arises when the chip is conveyed for die bonding and when the heat sink 110 is positioned, thus lowering the yield in mounting. FIG. 5 is a graph showing a relationship between the lifespan of the element and the thickness of the heat sink 110. When the thickness of the heat sink 110 exceeds 500 μm, the lifespan becomes 3,000 hours or less, causing a problem in practical use of the semiconductor laser device. This is the same result as in the case of the first embodiment. As described above, it is preferable for the thickness of the heat sink 110 to be 100 μm or more to 500 μm or less.

Next, the film thickness of the solder 113a which is to be transcribed is changed at the time when deposited onto a Teflon sheet so that an SnAgCu solder transcribing support base having varied thickness of the solder 113a is prepared, the same mounting as in the second embodiment is carried out, the yield in mounting is measured and the lifespan is evaluated. In the case where the thickness of the solder 113a is less than 1 μm, a sufficient joint strength is not obtained, and in the case where the thickness of the solder 113a is greater than 20 μm, deviation in an angle of a beam occurs, lowering the yield in mounting. Regarding the thickness of the solder 113a, the In solder 113 in the first embodiment exhibits the similar tendency, and in the case of less than 1 μm, a sufficient joint strength is not obtained, and in the case where the thickness of the solder 113 becomes greater than 20 μm, deviation in the angle of the beam occurs, lowering the yield in mounting. Accordingly, it is preferable for the thickness of the solder 113 or 113a to be 1 μm or more to 20 μm or less.

The present invention can be utilized in a semiconductor light emitting device wherein a semiconductor light emitting element chip such as a semiconductor laser chip or an LED chip is placed on and integrated with a mounting member.

1. A semiconductor light emitting device comprising:
a semiconductor light emitting element chip having a substrate made of a nitride-based compound semiconductor;
a heat sink made of SiC onto which the semiconductor light emitting element chip is mounted;
a first solder made of AuSn which joins the substrate to the heat sink;
a support base onto which the heat sink is mounted; and
a second solder made of SnAgCu or In which joins the heat sink to the support base.

2. The semiconductor light emitting device according to claim 1, wherein
the second solder has a thickness in a range from 1 μm or more to 20 μm or less.

3. The semiconductor light emitting device according to claim 1, wherein
the heat sink has a thickness in a range from 100 μm or more to 500 μm or less.

4. The semiconductor light emitting device according to claim 2, wherein
the heat sink has a thickness in a range from 100 μm or more to 500 μm or less.

5. A manufacturing method for a semiconductor light emitting device comprising a semiconductor light emitting element chip having a substrate made of a nitride-based compound semiconductor, a heat sink onto which the semiconductor light emitting element chip is mounted, a first solder which joins the substrate to the heat sink, a support base onto which the heat sink is mounted, and a second solder which joins the heat sink to the support base, the method comprising the steps of:
transcribing the second solder made of SnAgCu or In that has been fabricated in sheet form onto the support base; and
mounting a heat sink, onto which the semiconductor light emitting element chip has been mounted, onto the support base via the second solder.

6. The manufacturing method according to claim 5, wherein
the second solder has a thickness in a range from 1 μm or more to 20 μm or less.
